(19) United States
(12) Patent Application Publication
(10) Pub. No.: US 2023/0320121 A1
(43) Pub. Date: Oct. 5, 2023

(54) ORGANIC ELECTROLUMINESCENT DEVICE

(71) Applicant: BEIJING SUMMER SPROUT TECHNOLOGY CO., LTD., Beijing (CN)

(72) Inventors: Zhihao Cui, Beijing (CN); Renjie Zheng, Beijing (CN); Juntao Hu, Beijing (CN); Liang Gao, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/127,352

(22) Filed: Mar. 28, 2023

(30) Foreign Application Priority Data
Mar. 31, 2022 (CN) 202210322663.X

(51) Int. Cl. H10K 50/15; H10K 85/60

(52) U.S. Cl. CPC H10K 50/15; H10K 85/657; H10K 85/654; H10K 85/631; H10K 85/633; H10K 85/6572; H10K 85/621; H10K 85/626; H10K 85/6574; H10K 85/622; H10K 2101/30

(57) ABSTRACT

Provided is an organic electroluminescent device. The organic electroluminescent device comprises at least a first organic layer and a second organic layer, wherein the first organic layer has a relatively high electrical conductivity and comprises a first compound with deep LUMO and a second compound with deep HOMO and the second organic layer comprises a third compound having a high hole mobility. The compound combination can reduce an effect of an interface and provide better device performance, such as a reduced voltage and improved device efficiency. Further provided are a display apparatus comprising the organic electroluminescent device and an electronic equipment comprising the display apparatus.

### CROSS-REFERENCE TO RELATED APPLICATION(S)

This application claims priority to Chinese Patent Application No. 202210322663.X filed on Mar. 31, 2022, the disclosure of which is incorporated herein by reference in its entirety.

### TECHNICAL FIELD

The present disclosure relates to an organic electroluminescent device and, in particular, to an organic electroluminescent device comprising a particular material combination.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

A hole injection layer is an important function layer in an organic electroluminescent device. The current commercially available hole injection layer comprises a hole transporting material doped with a certain proportion of p-type conductive doping material, where a p-type doping effect is achieved through the strong ability of the p-type conductive doping material to capture electrons, improving a hole injection ability and electrical conductivity. The LUMO energy level of the current commercially available p-type conductive doping material is about −5.0 eV (such as PDA

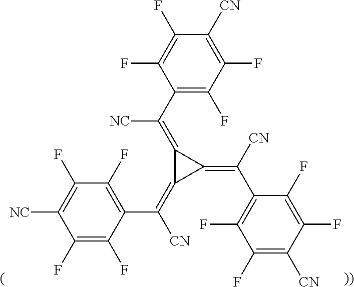 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

and the HOMO energy level of the commercially available hole transporting material is about −5.1 eV. However, the HOMO energy level of a host material in a commercially available light-emitting layer is about −5.4 eV, which is much deeper than that of the hole transporting material. A relatively large energy level difference between the host material and the hole transporting material limits the injection of holes from the transporting layer to the light-emitting layer, resulting in the excessive accumulation of holes at the interface therebetween and affecting device efficiency and lifetime. Although there are a wide variety of hole transporting materials at present, the commercially available p-type conductive doping material (such as PDA) cannot be effectively doped in the hole transporting material having a HOMO energy level of −5.2 eV or deeper so that it is difficult to effectively transfer charges, affecting the injection of holes from an anode and resulting in a larger voltage drop at the interface. Therefore, it is very important to develop the material combination of a p-type conductive doping material with deep LUMO and a hole transporting material with deep HOMO. The previous CN112909188A of the inventors discloses a p-type organic conductive doping material

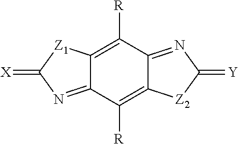

with deep LUMO and a hole transporting material

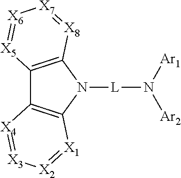

with deep HOMO. The combination of the two materials is used as a hole injection layer in an organic electroluminescent device. However, this application focuses on only the combination of the p-type organic conductive doping material and the hole transporting material and has not studied a relationship between the electrical conductivity of the hole injection layer, the hole mobility of the hole transporting material and device performance.

In summary, a hole injection layer and a hole transporting layer are important function layers affecting the performance of an organic electroluminescent device, and the selection and matching of materials of the hole injection layer and the hole transporting layer seriously affect the driving voltage, efficiency and lifetime of the organic electroluminescent device. Therefore, it is particularly important to develop and select an appropriate hole transporting material and material combination.

### SUMMARY

The present disclosure aims to provide an organic electroluminescent device comprising a particular material combination to solve at least part of the above problems. The organic electroluminescent device comprises at least a first organic layer and a second organic layer, wherein the first organic layer has a relatively high electrical conductivity and comprises a first compound with deep LUMO and a second compound with deep HOMO and the second organic layer comprises a third compound having a high hole mobility. The compound combination can reduce an effect of an interface and provide better device performance, such as a reduced voltage and improved device efficiency.

According to an embodiment of the present disclosure, disclosed is an organic electroluminescent device comprising:
a cathode,
an anode, and
a first organic layer and a second organic layer disposed between the cathode and the anode;
wherein the first organic layer comprises a first compound and a second compound and the second organic layer comprises a third compound;
the third compound may be the same as or different from the second compound; and
the LUMO energy level of the first compound is less than or equal to −5.15 eV, the HOMO energy level of the second compound is less than or equal to −5.20 eV; the hole mobility of the third compound is greater than or equal to 20×10⁻⁵ cm²/(Vs); and the electrical conductivity of the first organic layer is greater than or equal to 2×10⁻⁴ S/m.

According to another embodiment of the present disclosure, further disclosed is a display apparatus comprising the organic electroluminescent device described above.

According to another embodiment of the present disclosure, further disclosed is an electronic equipment comprising the display apparatus described above.

The present disclosure discloses an organic electroluminescent device comprising a particular material combination. The organic electroluminescent device comprises a first organic layer having a relatively high electrical conductivity and comprising a first compound with deep LUMO and a second compound with deep HOMO, and the organic electroluminescent device further comprises a second organic layer comprising a third compound having a high hole mobility. The particular combination can reduce the effect of an interface, reducing a voltage and improving device efficiency.

### BRIEF DESCRIPTION OF DRAWINGS

FIG. 1 is a schematic diagram of an organic light-emitting apparatus that may include an organic electroluminescent device disclosed herein.

FIG. 2 is a schematic diagram of another organic light-emitting apparatus that may include an organic electroluminescent device disclosed herein.

### DETAILED DESCRIPTION

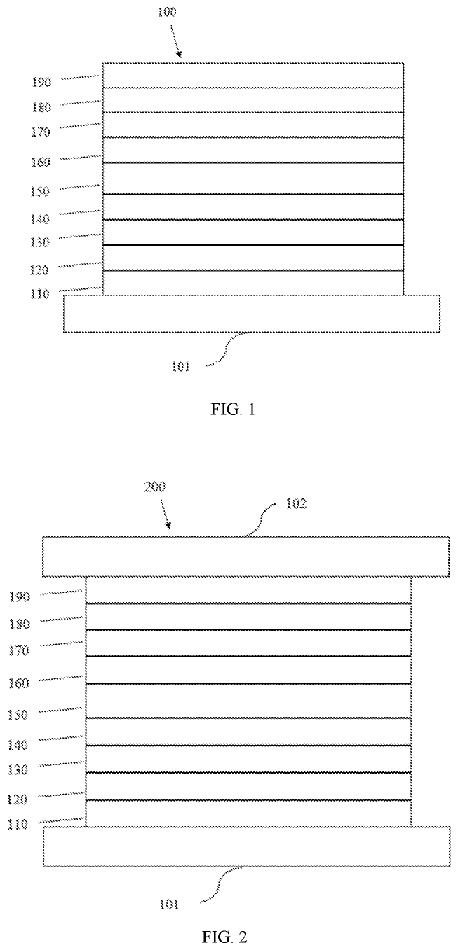

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T) Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small Δ_{ES-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

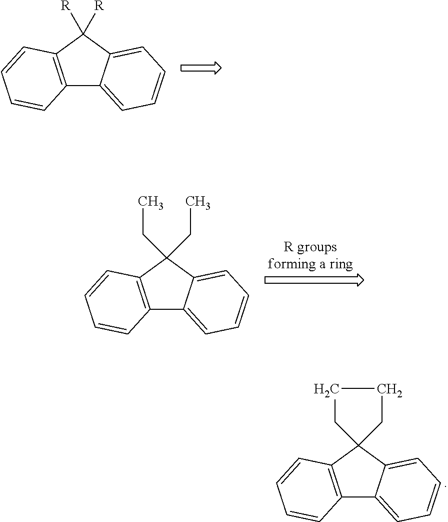

The expression that adjacent substituents can be optionally joined to form a ring is also intended to mean that two substituents bonded to carbon atoms which are directly bonded to each other are joined to each other via a chemical bond to form a ring, which can be exemplified by the following formula:

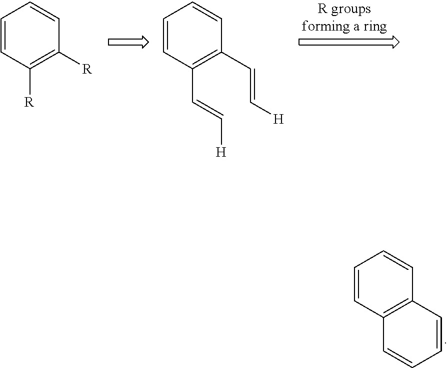

The expression that adjacent substituents can be optionally joined to form a ring is also intended to mean that two substituents bonded to a further distant carbon atom are joined to each other via a chemical bond to form a ring, which can be exemplified by the following formula:

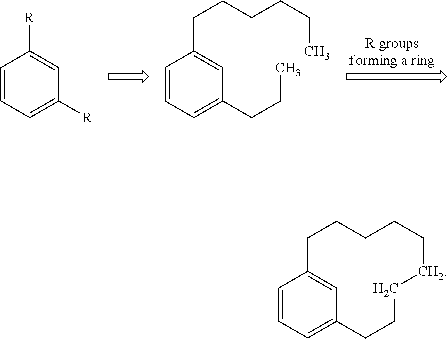

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

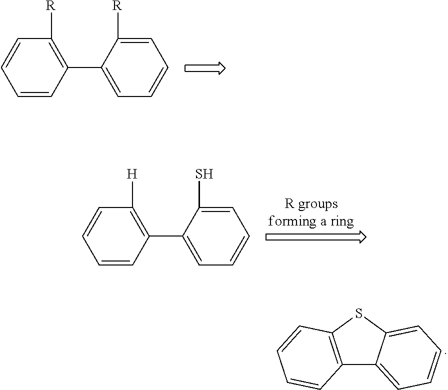

According to an embodiment of the present disclosure, disclosed is an organic electroluminescent device comprising:
a cathode,
an anode, and
a first organic layer and a second organic layer disposed between the cathode and the anode;
wherein the first organic layer comprises a first compound and a second compound and the second organic layer comprises a third compound;
the third compound may be the same as or different from the second compound; and
the LUMO energy level of the first compound is less than or equal to −5.15 eV, the HOMO energy level of the second compound is less than or equal to −5.20 eV; the hole mobility of the third compound is greater than or equal to 20×10⁻⁵ cm²/(Vs); and the electrical conductivity of the first organic layer is greater than or equal to 2×10⁻⁴ S/m.

According to an embodiment of the present disclosure, the LUMO energy level of the first compound is less than or equal to −5.16 eV.

According to an embodiment of the present disclosure, the LUMO energy level of the first compound is less than or equal to −5.17 eV.

According to an embodiment of the present disclosure, the LUMO energy level of the first compound is less than or equal to −5.18 eV.

According to an embodiment of the present disclosure, the LUMO energy level of the first compound is less than or equal to −5.19 eV.

According to an embodiment of the present disclosure, the LUMO energy level of the first compound is less than or equal to −5.20 eV.

According to an embodiment of the present disclosure, the LUMO energy level of the first compound is less than or equal to −5.21 eV.

According to an embodiment of the present disclosure, the LUMO energy level of the first compound is less than or equal to −5.22 eV.

According to an embodiment of the present disclosure, the LUMO energy level of the first compound is less than or equal to −5.23 eV.

According to an embodiment of the present disclosure, the HOMO energy level of the second compound is less than or equal to −5.21 eV.

According to an embodiment of the present disclosure, the HOMO energy level of the second compound is less than or equal to −5.22 eV.

According to an embodiment of the present disclosure, the HOMO energy level of the second compound is less than or equal to −5.23 eV.

According to an embodiment of the present disclosure, the HOMO energy level of the second compound is less than or equal to −5.24 eV.

According to an embodiment of the present disclosure, the HOMO energy level of the second compound is less than or equal to −5.25 eV.

According to an embodiment of the present disclosure, the HOMO energy level of the second compound is less than or equal to −5.26 eV.

According to an embodiment of the present disclosure, the HOMO energy level of the second compound is less than or equal to −5.27 eV.

According to an embodiment of the present disclosure, the HOMO energy level of the second compound is less than or equal to −5.28 eV.

According to an embodiment of the present disclosure, the hole mobility of the second compound is greater than or equal to 20×10⁻⁵ cm²/(Vs).

According to an embodiment of the present disclosure, the hole mobility of the second compound is greater than or equal to 21×10⁻⁵ cm²/(Vs).

According to an embodiment of the present disclosure, the hole mobility of the second compound is greater than or equal to 22×10⁻⁵ cm²/(Vs).

According to an embodiment of the present disclosure, the hole mobility of the second compound is greater than or equal to 23×10⁻⁵ cm²/(Vs).

According to an embodiment of the present disclosure, the hole mobility of the second compound is greater than or equal to 24×10⁻⁵ cm²/(Vs).

According to an embodiment of the present disclosure, the hole mobility of the second compound is greater than or equal to 25×10⁻⁵ cm²/(Vs).

According to an embodiment of the present disclosure, the hole mobility of the second compound is greater than or equal to 26×10⁻⁵ cm²/(Vs).

According to an embodiment of the present disclosure, the hole mobility of the third compound is greater than or equal to 21×10⁻⁵ cm²/(Vs).

According to an embodiment of the present disclosure, the hole mobility of the third compound is greater than or equal to 22×10⁻⁵ cm²/(Vs).

According to an embodiment of the present disclosure, the hole mobility of the third compound is greater than or equal to 23×10⁻⁵ cm²/(Vs).

According to an embodiment of the present disclosure, the hole mobility of the third compound is greater than or equal to 24×10⁻⁵ cm²/(Vs).

According to an embodiment of the present disclosure, the hole mobility of the third compound is greater than or equal to 25×10⁻⁵ cm²/(Vs).

According to an embodiment of the present disclosure, the hole mobility of the third compound is greater than or equal to 26×10⁻⁵ cm²/(Vs).

According to an embodiment of the present disclosure, the electrical conductivity of the first organic layer is greater than or equal to 3×10⁻⁴ S/m.

According to an embodiment of the present disclosure, the electrical conductivity of the first organic layer is greater than or equal to 4×10⁻⁴ S/m.

According to an embodiment of the present disclosure, the electrical conductivity of the first organic layer is greater than or equal to 5×10⁻⁴ S/m.

According to an embodiment of the present disclosure, the electrical conductivity of the first organic layer is greater than or equal to 6×10⁻⁴ S/m.

According to an embodiment of the present disclosure, the electrical conductivity of the first organic layer is greater than or equal to 7×10⁻⁴ S/m.

According to an embodiment of the present disclosure, the electrical conductivity of the first organic layer is greater than or equal to 8×10⁻⁴ S/m.

According to an embodiment of the present disclosure, the electrical conductivity of the first organic layer is greater than or equal to 9×10⁻⁴ S/m.

According to an embodiment of the present disclosure, the electrical conductivity of the first organic layer is greater than or equal to 10×10⁻⁴ S/m.

According to an embodiment of the present disclosure, an absolute value of an energy level difference between the LUMO energy level of the first compound and the HOMO energy level of the second compound is less than 0.15 eV.

According to an embodiment of the present disclosure, the absolute value of the energy level difference between the LUMO energy level of the first compound and the HOMO energy level of the second compound is less than 0.1 eV.

According to an embodiment of the present disclosure, the absolute value of the energy level difference between the LUMO energy level of the first compound and the HOMO energy level of the second compound is less than or equal to 0.05 eV.

According to an embodiment of the present disclosure, the doping mass ratio of the first compound to the second compound in the first organic layer is less than or equal to 10/90.

According to an embodiment of the present disclosure, the doping mass ratio of the first compound to the second compound is less than or equal to 7/93.

According to an embodiment of the present disclosure, the doping mass ratio of the first compound to the second compound is less than or equal to 5/95.

According to an embodiment of the present disclosure, the doping mass ratio of the first compound to the second compound is less than or equal to 3/97.

According to an embodiment of the present disclosure, the first compound has a structure represented by Formula 1:

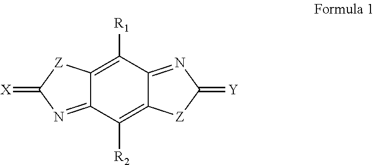

wherein Z is, at each occurrence identically or differently, selected from 0 or S;
X and Y are, at each occurrence identically or differently, selected from NR′, CR″R′″, O, S or Se;
R₁, R₂, R′, R″ and R′″ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof; and
at least one of R₁, R₂, R′, R″ and R′″ is a group having at least one electron-withdrawing group.

According to an embodiment of the present disclosure, Z is O.

According to an embodiment of the present disclosure, X and Y are, at each occurrence identically or differently, selected from NR′ or CR″R′″, and each of R′, R″ and R′″ is a group having at least one electron-withdrawing group.

According to an embodiment of the present disclosure, each of R₁, R₂, R′, R″ and R′″ is a group having at least one electron-withdrawing group.

According to an embodiment of the present disclosure, X and Y are, at each occurrence identically or differently, selected from O, S or Se, and at least one of R₁ and R₂ is a group having at least one electron-withdrawing group.

According to an embodiment of the present disclosure, X and Y are, at each occurrence identically or differently, selected from the group consisting of the following structures:
O, S, Se,

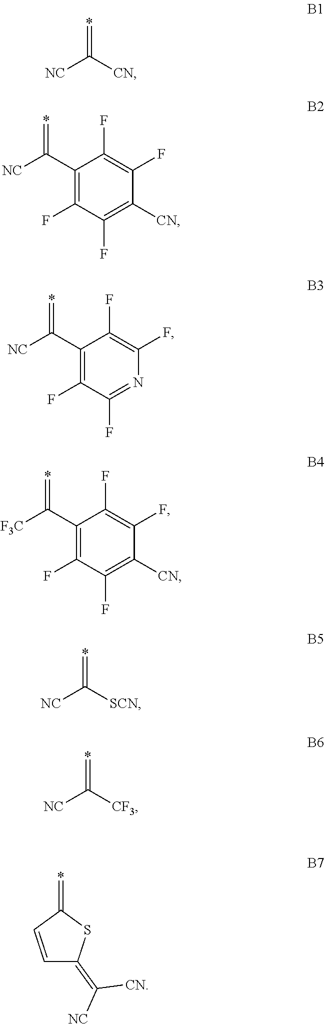

According to an embodiment of the present disclosure, each of X and Y is

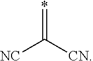 [SMILES: *=C(C#N)C#N]

According to an embodiment of the present disclosure, the Hammett constant of the electron-withdrawing group is greater than or equal to 0.05.

According to an embodiment of the present disclosure, the Hammett constant of the electron-withdrawing group is greater than or equal to 0.3.

According to an embodiment of the present disclosure, the Hammett constant of the electron-withdrawing group is greater than or equal to 0.5.

In the present disclosure, the Hammett constant of the electron-withdrawing group is greater than or equal to 0.05. The relatively strong electron-withdrawing ability can significantly reduce the LUMO energy level of the compound and improve charge mobility.

It is to be noted that the Hammett constant comprises a Hammett para constant and/or a Hammett meta constant, and as long as one of the para constant and the meta constant of a substituent is greater than or equal to 0.05, the substituent can be used as the preferred electron-withdrawing group of the present disclosure.

According to an embodiment of the present disclosure, the electron-withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, an aza-aromatic ring group and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, alkylgermanyl having 3 to 20 carbon atoms, arylgermanyl having 6 to 20 carbon atoms and combinations thereof.

According to an embodiment of the present disclosure, the electron-withdrawing group is selected from the group consisting of: F, CF₃, OCF₃, —SF₅, —SO₂CF₃, cyano, isocyano, SCN, OCN, pyrimidinyl, triazinyl and combinations thereof.

According to an embodiment of the present disclosure, R₁ and R₂ are, at each occurrence identically or differently, selected from the group consisting of: halogen, cyano, trifluoromethyl, trifluoromethoxy, isocyano, SCN, OCN, SF₅ and any one of the following groups substituted with one or more of F, OCF₃, CN and CF₃: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, aryl having 6 to 30 carbon atoms, heteroaryl having 3 to 30 carbon atoms and combinations thereof.

According to an embodiment of the present disclosure, R₁ and R₂ are, at each occurrence identically or differently, selected from the group consisting of: fluorine, cyano, trifluoromethyl, trifluoromethoxy and any one of the following groups substituted with one or more of F, OCF₃, CN and CF₃: aryl having 6 to 30 carbon atoms, heteroaryl having 3 to 30 carbon atoms and combinations thereof.

According to an embodiment of the present disclosure, R₁ and R₂ are, at each occurrence identically or differently, selected from the group consisting of A1 to A84, wherein the specific structures of A1 to A84 are referred to claim 15.

According to an embodiment of the present disclosure, the first compound is selected from the group consisting of Compound PD1 to Compound PD168, wherein the specific structures of Compound PD1 to Compound PD168 are referred to claim 16.

According to an embodiment of the present disclosure, the first compound has a molecular weight of greater than 230 g/mol.

According to an embodiment of the present disclosure, the second compound comprises any one or more chemical structural units selected from the group consisting of triarylamine, carbazole, fluorene, spirobifluorene, thiophene, furan, phenyl, oligophenylene ethylene, oligofluorene and combinations thereof.

According to an embodiment of the present disclosure, the second compound comprises a monotriarylamine structural unit or a bistriarylamine structural unit.

According to an embodiment of the present disclosure, the second compound comprises any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit and a bistriarylamine-fluorene structural unit.

According to an embodiment of the present disclosure, the second compound is a monotriarylamine compound or a bistriarylamine compound.

According to an embodiment of the present disclosure, the second compound is selected from a monotriarylamine-carbazole compound, a monotriarylamine-thiophene compound, a monotriarylamine-furan compound, a monotriarylamine-fluorene compound, a bistriarylamine-carbazole compound, a bistriarylamine-thiophene compound, a bistriarylamine-furan compound or a bistriarylamine-fluorene compound.

According to an embodiment of the present disclosure, the second compound comprising a monotriarylamine structural unit has a structure represented by Formula 2 or Formula 3:

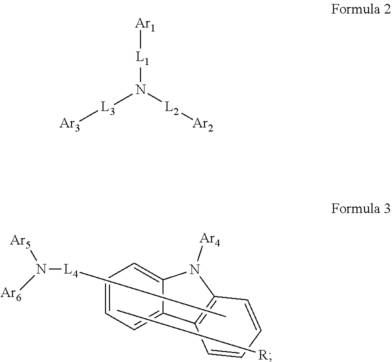

wherein Ar₁, Ar₂, Ar₃, Ar₄, Ar₅ and Ar₆ are, at each occurrence identically or differently, selected from substituted or unsubstituted aryl having 6 to 30 carbon atoms or substituted or unsubstituted heteroaryl having 3 to 30 carbon atoms; and the structures of Ar₁, Ar₂, Ar₃, Ar₄, Ar₅ and Ar₆ do not comprise carbazole;
L₁, L₂, L₃ and L₄ are, at each occurrence identically or differently, selected from a single bond, substituted or unsubstituted arylene having 6 to 30 carbon atoms, substituted or unsubstituted heteroarylene having 3 to 30 carbon atoms or a combination thereof; and the structures of L₁, L₂, L₃ and L₄ do not comprise carbazole;
R represents, at each occurrence identically or differently, mono-substitution, multiple substitutions or non-substitution; and
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and the structure of R does not comprise carbazole.

According to an embodiment of the present disclosure, Ar₁, Ar₂, Ar₃, Ar₄, Ar₆ and Ar₆ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridinyl, substituted or unsubstituted anthryl, substituted or unsubstituted pyrenyl, substituted or unsubstituted fluorenyl or a combination thereof.

According to an embodiment of the present disclosure, L₁, L₂, L₃ and L₄ are, at each occurrence identically or differently, selected from a single bond, substituted or unsubstituted phenylene, substituted or unsubstituted biphenylene, substituted or unsubstituted terphenylene, substituted or unsubstituted naphthylene, substituted or unsubstituted dibenzofurylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridinylene, substituted or unsubstituted anthrylene, substituted or unsubstituted pyrenylene, substituted or unsubstituted fluorenylene or a combination thereof.

According to an embodiment of the present disclosure, the second compound comprising a bistriarylamine structural unit has a structure represented by Formula 4:

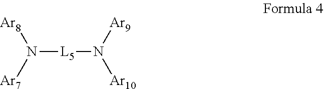

wherein Ar₇, Ar₈, Ar₉ and Ar₁₀ are selected from substituted or unsubstituted aryl having 6 to 30 carbon atoms or substituted or unsubstituted heteroaryl having 3 to 30 carbon atoms;
adjacent substituents Ar₇ and Ar₈ are not joined to form a ring, or adjacent substituents Ar₉ and Ar₁₀ are not joined to form a ring;
L₅ is selected from substituted or unsubstituted arylene having 6 to 30 carbon atoms or substituted or unsubstituted heteroarylene having 3 to 30 carbon atoms.

According to an embodiment of the present disclosure, Ar₇, Ar₈, Ar₉ and Ar₁₀ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted carbazolyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridinyl, substituted or unsubstituted anthryl, substituted or unsubstituted pyrenyl, substituted or unsubstituted fluorenyl or a combination thereof wherein adjacent substituents Ar₇ and Ar₈ are not joined to form a ring, or adjacent substituents Ar₉ and Ar₁₀ are not joined to form a ring.

According to an embodiment of the present disclosure, L₅ is selected from a single bond, substituted or unsubstituted phenylene, substituted or unsubstituted biphenylene, substituted or unsubstituted terphenylene, substituted or unsubstituted naphthylene, substituted or unsubstituted carbazolylene, substituted or unsubstituted dibenzofurylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridinylene, substituted or unsubstituted anthrylene, substituted or unsubstituted pyrenylene, substituted or unsubstituted fluorenylene or a combination thereof.

According to an embodiment of the present disclosure, the third compound comprises any one or more chemical structural units selected from the group consisting of triarylamine, carbazole, fluorene, spirobifluorene, thiophene, furan, phenyl, oligophenylene ethylene, oligofluorene and combinations thereof.

According to an embodiment of the present disclosure, the third compound is the same as the second compound.

According to an embodiment of the present disclosure, the first compound is a p-type conductive doping material and the second compound is a hole transporting material.

According to an embodiment of the present disclosure, the third compound is a hole transporting material.

According to an embodiment of the present disclosure, the p-type conductive doping material is an organic material.

According to an embodiment of the present disclosure, the organic electroluminescent device further comprises a light-emitting layer, wherein the second organic layer is disposed between the first organic layer and the light-emitting layer.

According to an embodiment of the present disclosure, the first organic layer is a hole injection layer and the second organic layer is a hole transporting layer.

According to an embodiment of the present disclosure, the organic electroluminescent device comprises multiple layers stacked between the anode and the cathode.

According to an embodiment of the present disclosure, disclosed is a display apparatus comprising the organic electroluminescent device described above.

According to an embodiment of the present disclosure, disclosed is an electronic equipment comprising the display apparatus described above.

Combination with Other Materials

The materials described in the present disclosure for a particular layer in an organic light-emitting device can be used in combination with various other materials present in the device. The combinations of these materials are described in more detail in U.S. Pat. Pub. No. US20160359122A1 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. Pub. No. US 20150349273A1, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The preparation methods of the selected compounds are not limited in the present disclosure, and those skilled in the art can prepare the selected compounds by conventional synthesis methods, which are not repeated here. The preparation method of an organic electroluminescent device is not limited. In the examples of the device, the characteristics of the device are also tested using conventional equipment in the art (including, but not limited to, an evaporator produced by ANGSTROM ENGINEERING, an optical testing system produced by SUZHOU FATAR, a lifetime testing system produced by SUZHOU FATAR, and an ellipsometer produced by BEIJING ELLITOP, etc.) by methods well-known to the persons skilled in the art. As the persons skilled in the art are aware of the above-mentioned equipment use, test methods and other related contents, the inherent data of the sample can be obtained with certainty and without influence, so the above related contents are not further described in the present disclosure. Preparation methods in the following device examples are only examples and not to be construed as limiting. Those skilled in the art can make reasonable improvements on the preparation methods in the following device examples based on the related art.

The HOMO energy levels and LUMO energy levels obtained herein were measured through cyclic voltammetry (CV). CV tests were conducted using a CorrTest CS120 electrochemical workstation produced by WUHAN CORRTEST INSTRUMENTS CORP., LTD. A three-electrode working system was used: a platinum disk electrode served as a working electrode, a Ag/AgNO₃ electrode served as a reference electrode, and a platinum wire electrode served as an auxiliary electrode; 0.1 mol/L tetrabutylammonium hexafluorophosphate was used as a supporting electrolyte; anhydrous DCM was used as a solvent, a compound to be tested was prepared into a solution of 10⁻³ mol/L; and nitrogen was introduced into the solution for 10 min for oxygen removal before the tests. The parameters of the instrument were set as follows: a scan rate of 100 mV/s, a potential interval of 0.5 mV and a test window of 1 V to −0.5 V.

The electrical conductivity obtained herein was measured by the following method: the first compound and the second compound were co-deposited through evaporation at a certain doping ratio and a vacuum degree of 10⁻⁶ Torr on a test substrate pre-prepared with aluminum electrodes to form a to-be-tested region with a thickness of 100 nm, a length of 6 mm and a width of 1 mm, the resistance value of the to-be-tested region was obtained by applying a voltage to the electrodes and measuring a current, and the electrical conductivity of the film was calculated according to the Ohm's law and the geometric dimensions.

The hole mobility obtained herein was measured by the following method: firstly, a glass substrate having a thickness of 0.7 mm and patterned with an indium tin oxide (ITO) anode with a thickness of 800 Å was washed with deionized water and a detergent, and then the ITO surface was treated with oxygen plasma and UV ozone. Then, the substrate was dried in a glovebox to remove moisture, mounted on a support and transferred into a vacuum chamber. The organic layers specified below were sequentially deposited on the anode layer through vacuum thermal evaporation at a rate of 0.01-10 Å/s and at a vacuum degree of about 10⁻⁶ Torr. Compound HT1

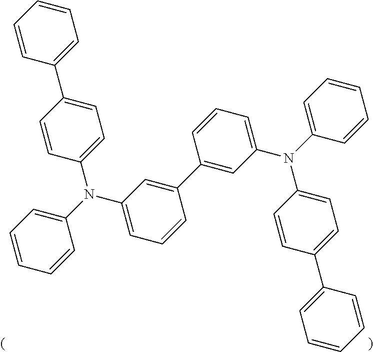 [SMILES: c1ccc(-c2ccc(N(c3ccccc3)c3cccc(-c4cccc(N(c5ccccc5)c5ccc(-c6ccccc6)cc5)c4)c3)cc2)cc1]

### and Compound PD35

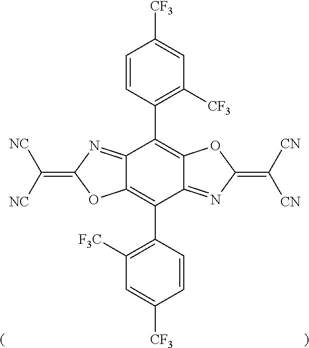 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1]

were co-deposited for use as a hole injection layer (HIL, 60:40, 100 Å). The to-be-tested sample was deposited thereon for use as a hole transporting layer (HTL, 1000 Å). Then, Compound HT1 and Compound PD35 were co-deposited for use as an electron blocking layer (EBL, 60:40, 100 A). Finally, the metal silver was deposited for use as a cathode (200 Å). The device was transferred back to the glovebox and encapsulated with a glass lid to complete the device. A layer using more than one material was obtained by doping different compounds at their weight ratio as recorded.

The hole mobility of the to-be-tested sample was calculated according to a Mott-Gurney equation:

$$μ = \frac{8 {d}^{3}}{9 {ε}_{0} {ε}_{r}} {( \frac{\sqrt{J}}{{V}_{a}} )}^{2}$$

wherein μ denotes the hole mobility of the to-be-tested sample (unit: m²/Vs), εᵣ denotes the relative permittivity of an organic material (εᵣ=3), εₒ denotes a vacuum permittivity (εₒ=8.85×10⁻¹² F/m), d denotes the thickness of the sample (unit: m), J denotes a current density (unit: A/m²), and Vₐ denotes an applied voltage (unit: V).

### Device Example

### Example 1

Firstly, a glass substrate having a thickness of 0.7 mm and patterned with an indium tin oxide (ITO) anode with a thickness of 800 Å was washed with deionized water and a detergent, and then the ITO surface was treated with oxygen plasma and UV ozone. Then, the substrate was dried in a glovebox to remove moisture, mounted on a support and transferred into a vacuum chamber. The organic layers specified below were sequentially deposited on the anode layer through vacuum thermal evaporation at a rate of 0.01-10 Å/s and at a vacuum degree of about 10⁻⁶ Torr. The second compound HT1 and the first compound PD56 were co-deposited for use as a hole injection layer (HIL, 98:2, 100 Å). The third compound HT1 the same as the second compound was deposited for use as a hole transporting layer (HTL, 1500 Å). On the HTL, Compound BH and Compound BD were co-deposited for use as an emissive layer (EML, 96:4, 250 Å). Compound HB was deposited for use as a hole blocking layer (HBL, 50 Å). On the HBL, Compound ET and 8-hydroxyquinolinolato-lithium (Liq) were co-deposited for use as an electron transporting layer (ETL, 40:60, 300 Å). Liq was deposited for use as an electron injection layer (EIL) with a thickness of 10 Å. Finally, the metal aluminum was deposited for use as a cathode (1200 Å). The device was transferred back to the glovebox and encapsulated with a glass lid to complete the device.

Example 2: This example was prepared by the same method as Example 1 except that the second compound HT1 and the first compound PD80 were deposited for use as a hole injection layer (HIL, 98:2, 100 Å).

Example 3: This example was prepared by the same method as Example 1 except that the second compound HT1 and the first compound PD67 were deposited for use as a hole injection layer (HIL, 98:2, 100 Å).

Example 4: This example was prepared by the same method as Example 1 except that the second compound HT2 and the first compound PD56 were deposited for use as a hole injection layer (HIL, 98:2, 100 Å) and the third compound HT2 the same as the second compound was deposited for use as a hole transporting layer (HTL, 1500 Å).

Example 5: This example was prepared by the same method as Example 1 except that the second compound HT2 and the first compound PD80 were deposited for use as a hole injection layer (HIL, 98:2, 100 Å) and the third compound HT2 the same as the second compound was deposited for use as a hole transporting layer (HTL, 1500 Å).

Example 6: This example was prepared by the same method as Example 1 except that the second compound HT2 and the first compound PD67 were deposited for use as a hole injection layer (HIL, 98:2, 100 Å) and the third compound HT2 the same as the second compound was deposited for use as a hole transporting layer (HTL, 1500 Å).

Comparative Example 1: This comparative example was prepared by the same method as Example 1 except that Compound HT3 and Compound PDA were deposited for use as a hole injection layer (HIL, 98:2, 100 Å) and Compound HT3 was deposited for use as a hole transporting layer (HTL, 1500 Å).

Comparative Example 2: This comparative example was prepared by the same method as Example 1 except that Compound HT3 and Compound PD80 were deposited for use as a hole injection layer (HIL, 97:3, 100 Å) and Compound HT3 was deposited for use as a hole transporting layer (HTL, 1500 Å).

Comparative Example 3: This comparative example was prepared by the same method as Example 1 except that Compound HT1 and Compound PDA were deposited for use as a hole injection layer (HIL, 98:2, 100 Å).

Comparative Example 4: This comparative example was prepared by the same method as Example 1 except that Compound HT1 and Compound PDA were deposited for use as a hole injection layer (HIL, 97:3, 100 Å).

Comparative Example 5: This comparative example was prepared by the same method as Example 1 except that Compound HT1 and Compound PD42 were deposited for use as a hole injection layer (HIL, 99:1, 100 Å).

Comparative Example 6: This comparative example was prepared by the same method as Example 1 except that Compound HT2 and Compound PD42 were deposited for use as a hole injection layer (HIL, 99:1, 100 Å) and Compound HT2 was deposited for use as a hole transporting layer (HTL, 1500 Å).

Comparative Example 7: This comparative example was prepared by the same method as Example 1 except that Compound HT4 and Compound PD35 were deposited for use as a hole injection layer (HIL, 97:3, 100 Å) and Compound HT4 was deposited for use as a hole transporting layer (HTL, 1500 Å).

Comparative Example 8: This comparative example was prepared by the same method as Example 1 except that Compound HT5 and Compound PD35 were deposited for use as a hole injection layer (HIL, 97:3, 100 Å) and Compound HT5 was deposited for use as a hole transporting layer (HTL, 1500 Å).

Comparative Example 9: This comparative example was prepared by the same method as Example 1 except that Compound HT6 and Compound PD80 were deposited for use as a hole injection layer (HIL, 98:2, 100 Å) and Compound HT6 was deposited for use as a hole transporting layer (HTL, 1500 Å).

Comparative Example 10: This comparative example was prepared by the same method as Example 1 except that Compound HT6 and Compound PD80 were deposited for use as a hole injection layer (HIL, 97:3, 100 Å) and Compound HT6 was deposited for use as a hole transporting layer (HTL, 1500 Å).

The structures and thicknesses of some layers of the devices are shown in Table 1. A layer using more than one material is obtained by doping different compounds at their weight ratio as recorded.

TABLE 1
Part of the device structures of Examples
1 to 6 and Comparative Examples 1 to 10

| | HIL | HTL |
|---|---|---|
| Example 1 | HT1:PD56 (98:2) (100 Å) | HT1 (1500 Å) |
| Example 2 | HT1:PD80 (98:2) (100 Å) | HT1 (1500 Å) |
| Example 3 | HT1:PD67 (98:2) (100 Å) | HT1 (1500 Å) |
| Example 4 | HT2:PD56 (98:2) (100 Å) | HT2 (1500 Å) |
| Example 5 | HT2:PD80 (98:2) (100 Å) | HT2 (1500 Å) |
| Example 6 | HT2:PD67 (98:2) (100 Å) | HT2 (1500 Å) |
| Comparative | HT3:PDA (98:2) (100 Å) | HT3 (1500 Å) |
| Example 1 | | |
| Comparative | HT3:PD80 (97:3) (100 Å) | HT3 (1500 Å) |
| Example 2 | | |
| Comparative | HT1:PDA (98:2) (100 Å) | HT1 (1500 Å) |
| Example 3 | | |
| Comparative | HT1:PDA (97:3) (100 Å) | HT1 (1500 Å) |
| Example 4 | | |
| Comparative | HT1:PD42 (99:1) (100 Å) | HT1 (1500 Å) |
| Example 5 | | |
| Comparative | HT2:PD42 (99:1) (100 Å) | HT2 (1500 Å) |
| Example 6 | | |
| Comparative | HT4:PD35 (97:3) (100 Å) | HT4 (1500 Å) |
| Example 7 | | |
| Comparative | HT5:PD35 (97:3) (100 Å) | HT5 (1500 Å) |
| Example 8 | | |
| Comparative | HT6:PD80 (98:2) (100 Å) | HT6 (1500 Å) |
| Example 9 | | |
| Comparative | HT6:PD80 (97:3) (100 Å) | HT6 (1500 Å) |
| Example 10 | | |

The materials used in the devices have the following structures:

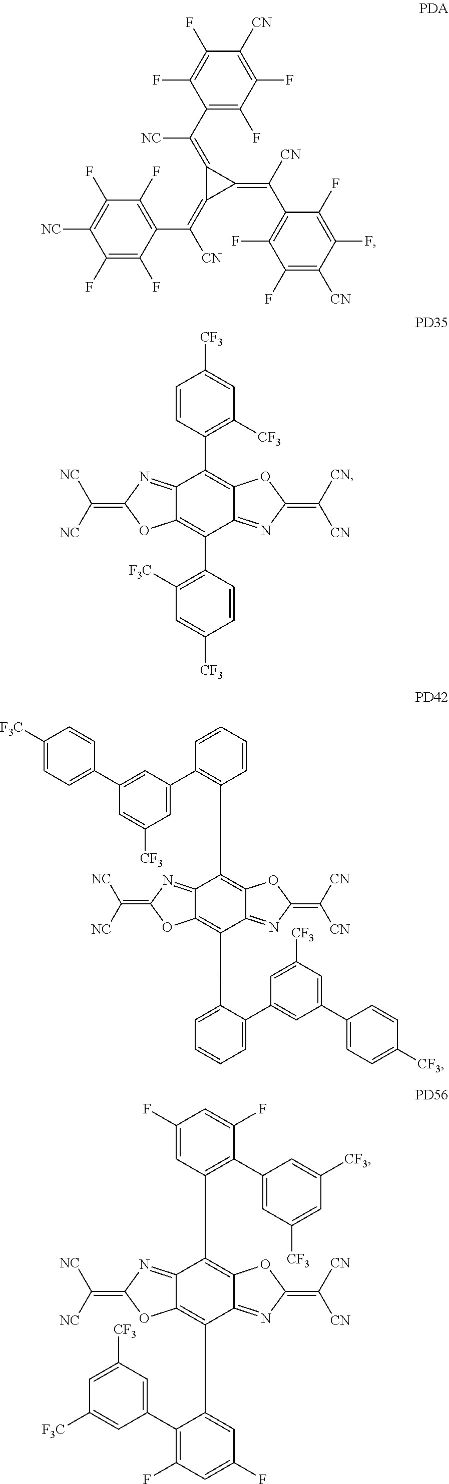 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(C#N)=c1nc2c(-c3ccccc3-c3cc(-c4ccc(C(F)(F)F)cc4)cc(C(F)(F)F)c3)c3oc(=C(C#N)C#N)nc3c(-c3ccccc3-c3cc(-c4ccc(C(F)(F)F)cc4)cc(C(F)(F)F)c3)c2o1 ; N#CC(C#N)=c1nc2c(-c3cc(F)cc(F)c3-c3cc(C(F)(F)F)cc(C(F)(F)F)c3)c3oc(=C(C#N)C#N)nc3c(-c3cc(F)cc(F)c3-c3cc(C(F)(F)F)cc(C(F)(F)F)c3)c2o1]

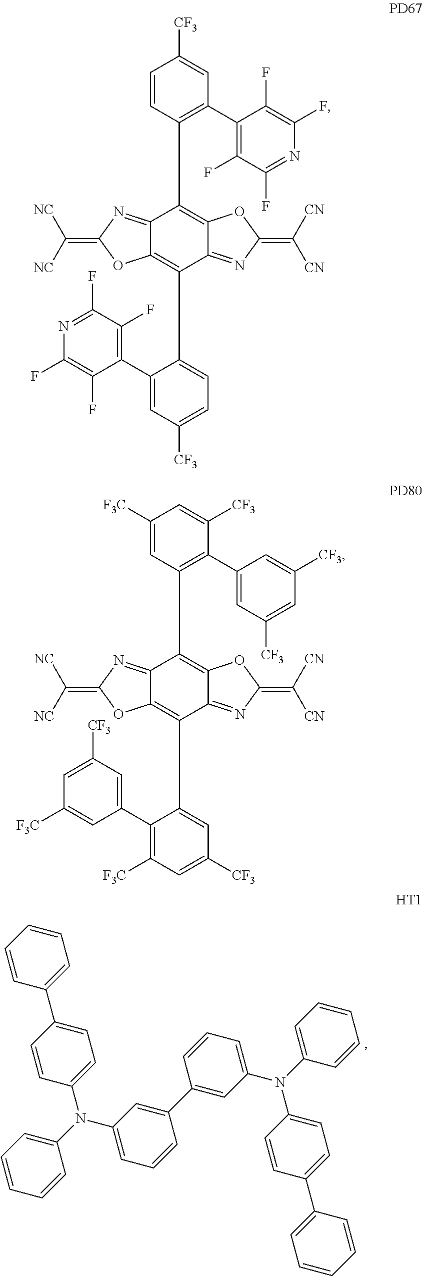

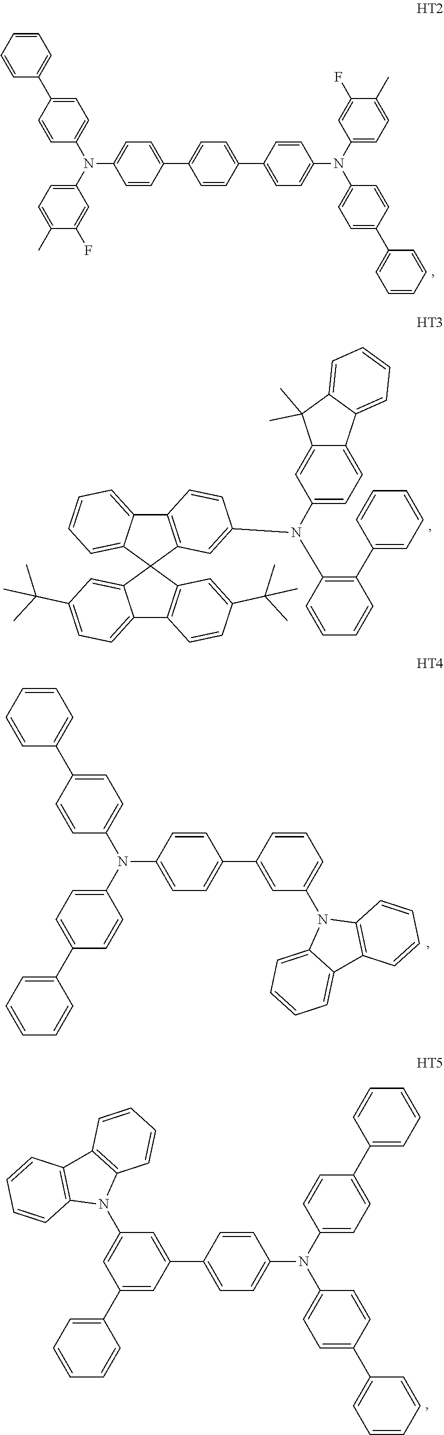 [SMILES: Cc1ccc(N(c2ccc(-c3ccccc3)cc2)c2ccc(-c3ccc(-c4ccc(N(c5ccc(-c6ccccc6)cc5)c5ccc(C)c(F)c5)cc4)cc3)cc2)cc1F ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4ccccc4)cc3)c3ccc(-c4cc(-c5ccccc5)cc(-n5c6ccccc6c6ccccc65)c4)cc3)cc2)cc1]

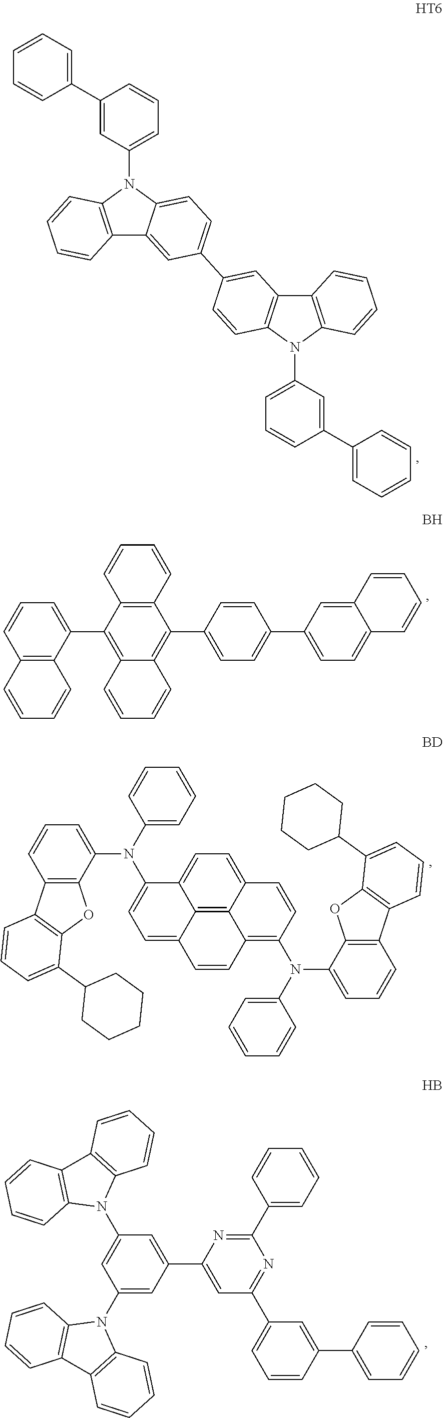

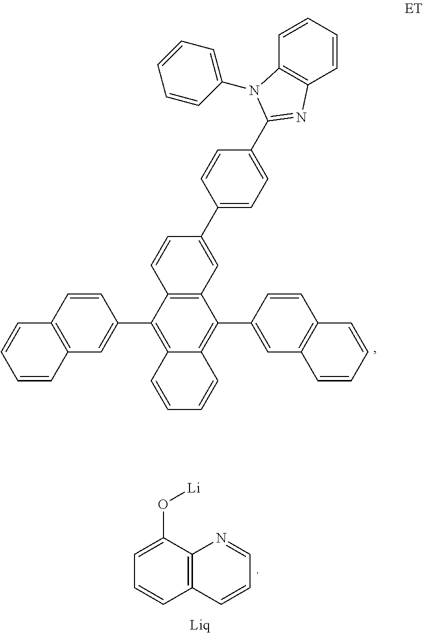

Table 2 shows the voltages, current efficiency (CE), power efficiency (PE) and external quantum efficiency (EQE) of the devices measured at a constant current of 10 mA/cm².

TABLE 2
Device data of Examples 1 to 6 and Comparative Examples 1 to 10

| Device No. | Voltage (V) | CE (cd/A) | PE (lm/W) | EQE (%) |
|---|---|---|---|---|
| Example 1 | 4.08 | 5.46 | 4.20 | 6.56 |
| Example 2 | 4.10 | 5.49 | 4.21 | 6.60 |
| Example 3 | 4.08 | 5.47 | 4.20 | 6.58 |
| Example 4 | 4.16 | 5.28 | 3.99 | 6.27 |
| Example 5 | 4.16 | 5.29 | 4.00 | 6.29 |
| Example 6 | 4.16 | 5.28 | 3.99 | 6.27 |
| Comparative | 4.27 | 4.63 | 3.40 | 5.56 |
| Example 1 | | | | |
| Comparative | 4.29 | 4.68 | 3.43 | 5.65 |
| Example 2 | | | | |
| Comparative | 5.82 | 6.57 | 3.55 | 7.84 |
| Example 3 | | | | |
| Comparative | 5.07 | 6.46 | 4.00 | 7.69 |
| Example 4 | | | | |
| Comparative | 8.04 | 6.97 | 2.72 | 8.24 |
| Example 5 | | | | |
| Comparative | 6.84 | 6.59 | 3.03 | 7.04 |
| Example 6 | | | | |
| Comparative | 4.74 | 5.61 | 3.72 | 6.55 |
| Example 7 | | | | |
| Comparative | 4.60 | 7.26 | 4.96 | 8.18 |
| Example 8 | | | | |
| Comparative | 6.94 | 4.72 | 2.14 | 5.55 |
| Example 9 | | | | |
| Comparative | 7.03 | 4.81 | 2.15 | 5.60 |
| Example 10 | | | | |

Table 3 shows the data about the LUMO energy level of the p-type conductive doping material and the HOMO energy level of the hole transporting material in the HIL, the electrical conductivity of the HIL and the hole mobility of the hole transporting material in the HTL in each of Examples 1 to 6 and Comparative Examples 1 to 10.

TABLE 3
Data about the device parameters of Examples
1 to 6 and Comparative Examples 1 to 10

| | | | Electrical | Hole |
|---|---|---|---|---|
| | LUMO | HOMO | Conductivity | Mobility |
| Device ID | (eV) | (eV) | (S/m) | (cm²/Vs) |
| Example 1 | −5.26 | −5.33 | 8.8 × 10⁻⁴ | 87 × 10⁻⁵ |
| Example 2 | −5.28 | −5.33 | 8.7 × 10⁻⁴ | 87 × 10⁻⁵ |
| Example 3 | −5.28 | −5.33 | 12.6 × 10⁻⁴ | 87 × 10⁻⁵ |
| Example 4 | −5.26 | −5.26 | 45.8 × 10⁻⁴ | 50 × 10⁻⁵ |
| Example 5 | −5.28 | −5.26 | 57.0 × 10⁻⁴ | 50 × 10⁻⁵ |
| Example 6 | −5.28 | −5.26 | 46.9 × 10⁻⁴ | 50 × 10⁻⁵ |
| Comparative | −5.04 | −5.13 | 11.6 × 10⁻⁴ | 31 × 10⁻⁵ |
| Example 1 | | | | |
| Comparative | −5.28 | −5.13 | 8.0 × 10⁻⁴ | 31 × 10⁻⁵ |
| Example 2 | | | | |
| Comparative | −5.04 | −5.33 | 2.8 × 10⁻⁴ | 87 × 10⁻⁵ |
| Example 3 | | | | |
| Comparative | −5.04 | −5.33 | 4.5 × 10⁻⁴ | 87 × 10⁻⁵ |
| Example 4 | | | | |
| Comparative | −5.16 | −5.33 | 0.3 × 10⁻⁴ | 87 × 10⁻⁵ |
| Example 5 | | | | |
| Comparative | −5.16 | −5.26 | 0.5 × 10⁻⁴ | 50 × 10⁻⁵ |
| Example 6 | | | | |
| Comparative | −5.17 | −5.26 | 3.4 × 10⁻⁴ | 16 × 10⁻⁵ |
| Example 7 | | | | |
| Comparative | −5.17 | −5.27 | 6.2 × 10⁻⁴ | 18 × 10⁻⁵ |
| Example 8 | | | | |
| Comparative | −5.28 | −5.36 | 3.1 × 10⁻⁴ | 4 × 10⁻⁵ |
| Example 9 | | | | |
| Comparative | −5.28 | −5.36 | 5.2 × 10⁻⁴ | 4 × 10⁻⁵ |
| Example 10 | | | | |

Discussion:

As can be seen from the data in Table 2 and Table 3, although the electrical conductivity of the HIL and the hole mobility of the hole transporting material in the HTL in each of Comparative Examples 1 and 2 and Examples 1 to 6 are relatively high, the HOMO energy level of the hole transporting material HT3 in Comparative Examples 1 and 2 is relatively shallow (−5.13 eV) and the potential barrier between the HOMO energy level of the material HT3 and the HOMO energy level of the host material is relatively high, resulting in the accumulation of a large number of holes at the interface between the material HT3 and the host material so that the devices exhibit relatively poor device performance including a high voltage and low efficiency; while the LUMO energy levels of the p-type conductive doping materials (the first compounds) in Examples 1 to 6 are less than −5.15 eV, the HOMO energy levels of the hole transporting materials (the second compounds) are less than −5.20 eV, and the LUMO energy levels of the p-type conductive doping materials and the HOMO energy levels of the hole transporting materials are all relatively deep so that effective charge transfer can occur, ensuring the efficient injection of holes from an ITO interface, and the potential barrier between the HOMO energy level of the hole transporting material and the HOMO energy level of the host material is relatively small, increasing the number of holes injected from the hole transporting layer to the light-emitting layer and making charges in the light-emitting layer more balanced. Therefore, compared with Comparative Examples 1 and 2, Examples 1 to 6 have the voltages reduced by 0.11 V to 0.21 V, the current efficiency (CE) increased by 12.8% to 18.6%, the power efficiency (PE) increased by 16.3% to 23.8% and the external quantum efficiency (EQE) increased by 11.0% to 18.7%, proving that the combination of the first compound having a deep LUMO energy level and the second compound having a deep HOMO energy level selected in the present application plays an important role in improving device performance.

The LUMO energy level of the p-type conductive doping material PDA in Comparative Examples 3 and 4 is −5.04 eV and higher than −5.15 eV and the energy level difference between the LUMO energy level of the p-type conductive doping material PDA and the HOMO energy level (−5.33 eV) of the hole transporting material HT1 is relatively large so that the effective charge transfer cannot be formed, severely limiting the injection of holes from ITO to the hole transporting layer and resulting in an increased voltage drop at the interface; and the LUMO energy levels of the p-type conductive doping materials (the first compounds) and the HOMO energy level of the hole transporting material (the second compounds) in Examples 1 to 3 are relatively deep, achieving high charge transfer efficiency, greatly improving the injection efficiency of holes from the ITO, and reducing the voltage drop at the interface. Compared with Comparative Examples 3 and 4, Examples 1 to 3 have the voltages reduced by 0.97 V to 1.74 V and the power efficiency (PE) increased by 5.0% to 18.6%, proving again that the combination of the first compound having a deep LUMO energy level and the second compound having a deep HOMO energy level selected in the present application plays an important role in improving the device performance.

The electrical conductivities of the hole injection layers in Comparative Examples 5 and 6 are only 0.3×10⁻⁴ S/m and 0.5×10⁻⁴ S/m, which are very low, resulting in a very small number of carriers in the hole injection layer and severely affecting the hole transporting efficiency of the entire hole transporting end; and the electrical conductivities of the hole injection layers (the first organic layers) in Examples 1 to 6 are greater than 4×10⁻⁴ S/m so that the number of carriers in the hole injection layer is relatively large, improving the hole transporting efficiency. Therefore, compared with Comparative Examples 5 and 6, Examples 1 to 6 have the device voltages reduced by 2.68 V to 3.96 V and the power efficiency (PE) increased by 31.7% to 54.8%, proving that the hole injection layer selected in the present application, which has a high electrical conductivity, plays an important role in improving the device performance.

The hole mobilities of the hole transporting materials in the hole transporting layers in Comparative Examples 7 to 10 are lower than 20×10⁻⁵ cm²/(Vs), and particularly, the hole mobility of the hole transporting material in Comparative Examples 9 and 10 is only 4×10⁻⁵ cm²/(Vs), resulting in increased resistance and a higher voltage at the hole transporting end; while the hole mobilities of the hole transporting materials (the third compounds) in the hole transporting layers (the second organic layers) in Examples 1 to 6 are greater than 20×10⁻⁵ cm²/(Vs). Therefore, compared with Comparative Examples 7 to 10, Examples 1 to 6 have the voltages reduced by 0.44 V to 2.95 V, proving that the third compound selected in the present application, which has a high hole mobility, plays an important role in improving the device performance.

In summary, the present disclosure discloses an organic electroluminescent device, where the organic electroluminescent device comprises at least the first organic layer and the second organic layer, the first organic layer has a relatively high electrical conductivity and comprises the first compound with deep LUMO and the second compound with deep HOMO, and the second organic layer comprises the third compound having a high hole mobility. The compound combination implements the effective doping of a p-type conductive material and can reduce the effect of the interface and provide better device performance.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising:
a cathode,
an anode, and
a first organic layer and a second organic layer disposed between the cathode and the anode;
wherein the first organic layer comprises a first compound and a second compound and the second organic layer comprises a third compound;
the third compound may be the same as or different from the second compound; and
a lowest unoccupied molecular orbital (LUMO) energy level of the first compound is less than or equal to −5.15 eV, a highest occupied molecular orbital (HOMO) energy level of the second compound is less than or equal to −5.20 eV; a hole mobility of the third compound is greater than or equal to 20×10⁻⁵ cm²/(Vs); and an electrical conductivity of the first organic layer is greater than or equal to 2×10⁻⁴ S/m.

2. The organic electroluminescent device according to claim 1, wherein the LUMO energy level of the first compound is less than or equal to −5.18 eV; preferably, the LUMO energy level of the first compound is less than or equal to −5.20 eV; more preferably, the LUMO energy level of the first compound is less than or equal to −5.22 eV.

3. The organic electroluminescent device according to claim 1, wherein the HOMO energy level of the second compound is less than or equal to −5.22 eV; preferably, the HOMO energy level of the second compound is less than or equal to −5.25 eV; more preferably, the HOMO energy level of the second compound is less than or equal to −5.28 eV.

4. The organic electroluminescent device according to claim 1, wherein a hole mobility of the second compound is greater than or equal to 20×10⁻⁵ cm²/(Vs); preferably, the hole mobility of the second compound is greater than or equal to 22×10⁻⁵ cm²/(Vs); more preferably, the hole mobility of the second compound is greater than or equal to 24×10⁻⁵ cm²/(Vs); most preferably, the hole mobility of the second compound is greater than or equal to 26×10⁻⁵ cm²/(Vs).

5. The organic electroluminescent device according to claim 1, wherein the hole mobility of the third compound is greater than or equal to 22×10⁻⁵ cm²/(Vs); preferably, the hole mobility of the third compound is greater than or equal to 24×10⁻⁵ cm²/(Vs); more preferably, the hole mobility of the third compound is greater than or equal to 26×10⁻⁵ cm²/(Vs).

6. The organic electroluminescent device according to claim 1, wherein the electrical conductivity of the first organic layer is greater than or equal to 3×10⁻⁴ S/m; preferably, the electrical conductivity of the first organic layer is greater than or equal to 5×10⁻⁴ S/m; more preferably, the electrical conductivity of the first organic layer is greater than or equal to 7×10⁻⁴ S/m; most preferably, the electrical conductivity of the first organic layer is greater than or equal to 10×10⁻⁴ S/m.

7. The organic electroluminescent device according to claim 1, wherein an absolute value of an energy level difference between the LUMO energy level of the first compound and the HOMO energy level of the second compound is less than 0.15 eV; preferably, the absolute value of the energy level difference between the LUMO energy level of the first compound and the HOMO energy level of the second compound is less than 0.1 eV; more preferably, the absolute value of the energy level difference between the LUMO energy level of the first compound and the HOMO energy level of the second compound is less than or equal to 0.05 eV.

8. The organic electroluminescent device according to claim 1, wherein the first compound has a structure represented by Formula 1: 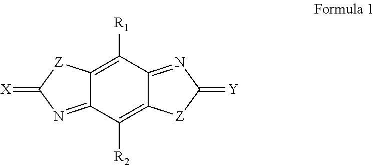
wherein Z is, at each occurrence identically or differently, selected from 0 or S;
X and Y are, at each occurrence identically or differently, selected from NR′, CR″R′″, O, S or Se;
R₁, R₂, R′, R″ and R′″ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof; and
at least one of R₁, R₂, R′, R″ and R′″ is a group having at least one electron-withdrawing group.

9. The organic electroluminescent device according to claim 8, wherein Z is O.

10. The organic electroluminescent device according to claim 8, wherein X and Y are, at each occurrence identically or differently, selected from NR′ or CR″R′″, and each of R′, R″ and R′″ is a group having at least one electron-withdrawing group.

11. The organic electroluminescent device according to claim 8, wherein X and Y are, at each occurrence identically or differently, selected from the group consisting of the following structures:
O, S, Se, 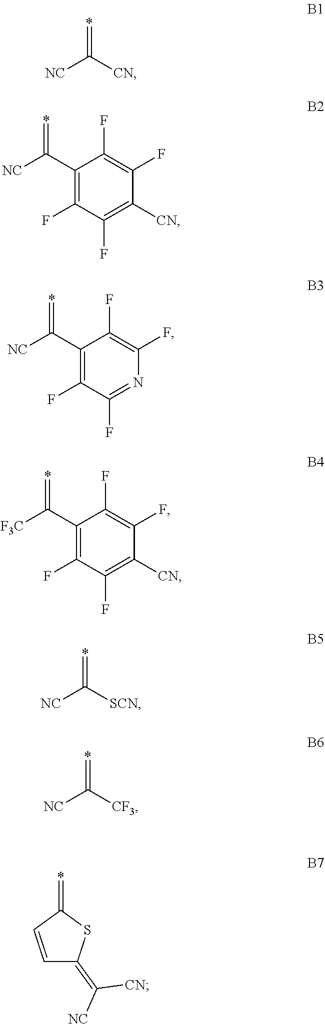
preferably, each of X and Y is

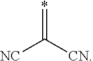 [SMILES: *=C(C#N)C#N]

12. The organic electroluminescent device according to claim 8, wherein a Hammett constant of the electron-withdrawing group is greater than or equal to 0.05; preferably, the Hammett constant of the electron-withdrawing group is greater than or equal to 0.3; more preferably, the Hammett constant of the electron-withdrawing group is greater than or equal to 0.5.

13. The organic electroluminescent device according to claim 8, wherein the electron-withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfonyl group, a sulfonyl group, a phosphoroso group, an aza-aromatic ring group and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfonyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, alkylgermanyl having 3 to 20 carbon atoms, arylgermanyl having 6 to 20 carbon atoms and combinations thereof;
preferably, the electron-withdrawing group is selected from the group consisting of: F, CF₃, OCF₃, SF₅, SO₂CF₃, cyano, isocyano, SCN, OCN, pyrimidinyl, triazinyl and combinations thereof.

14. The organic electroluminescent device according to claim 8, wherein R₁ and R₂ are, at each occurrence identically or differently, selected from the group consisting of: halogen, cyano, trifluoromethyl, trifluoromethoxy, isocyano, SCN, OCN, SF₅ and any one of the following groups substituted with one or more of F, OCF₃, CN and CF₃: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, aryl having 6 to 30 carbon atoms, heteroaryl having 3 to 30 carbon atoms and combinations thereof;
preferably, R₁ and R₂ are, at each occurrence identically or differently, selected from the group consisting of: fluorine, cyano, trifluoromethyl, trifluoromethoxy and any one of the following groups substituted with one or more of F, OCF₃, CN and CF₃: aryl having 6 to 30 carbon atoms, heteroaryl having 3 to 30 carbon atoms and combinations thereof.

15. The organic electroluminescent device according to claim 8, wherein R₁ and R₂ are, at each occurrence identically or differently, selected from the group consisting of:

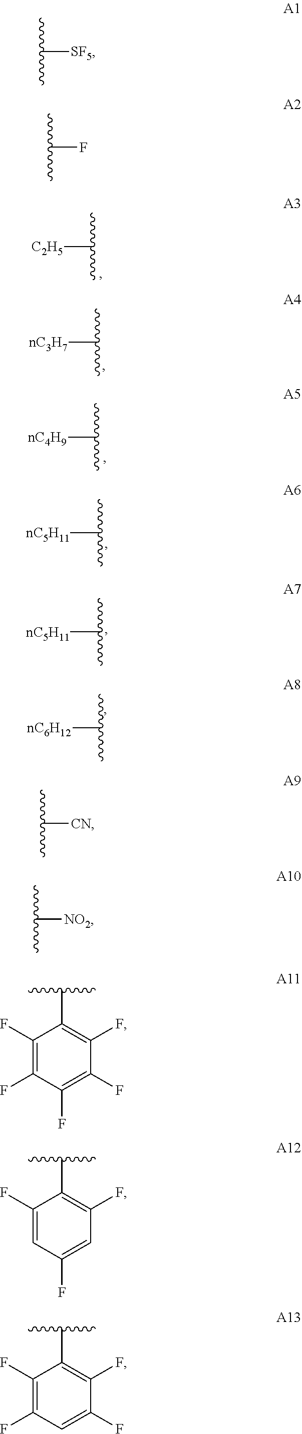

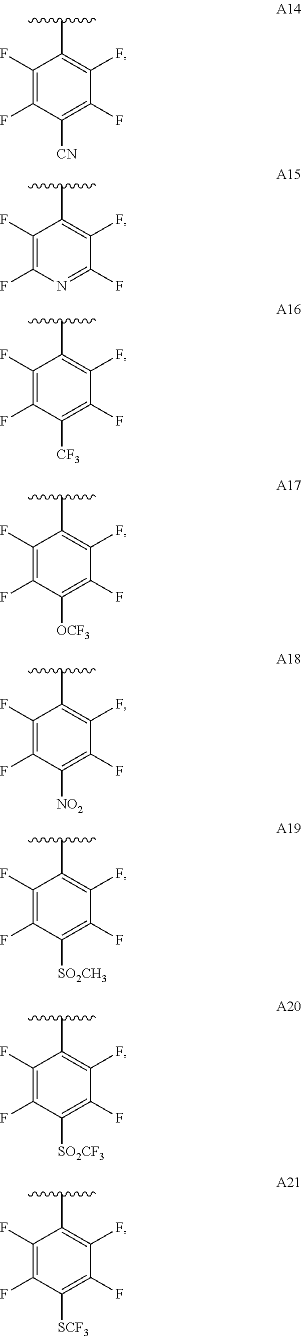

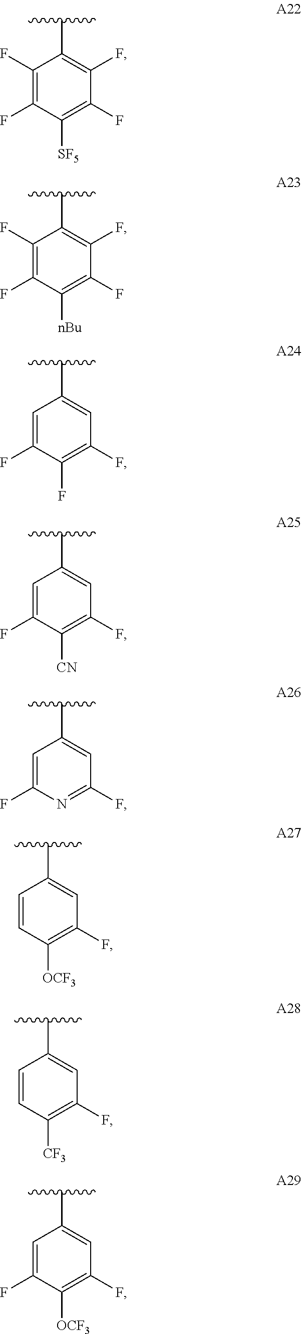

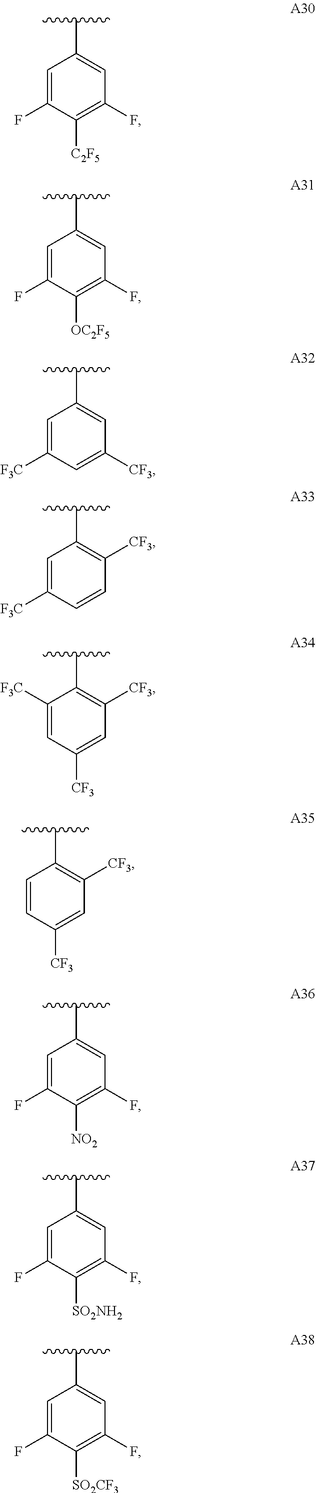

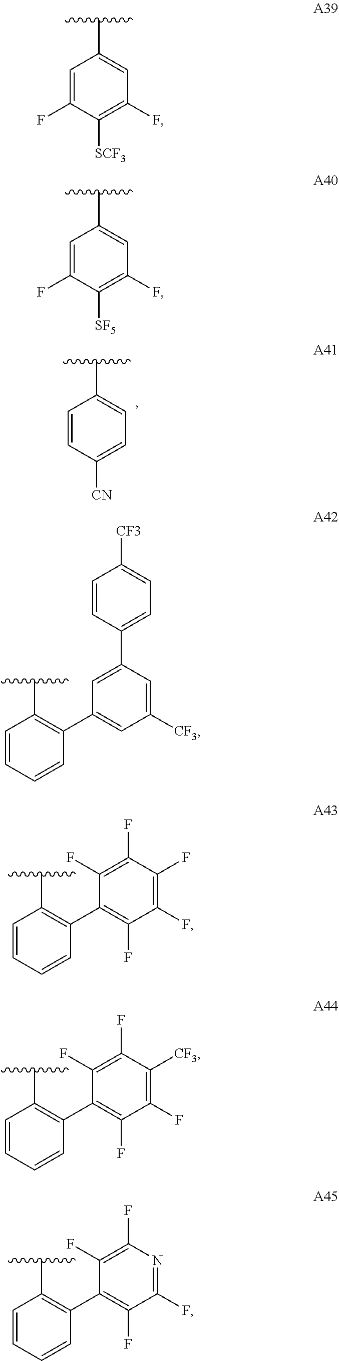

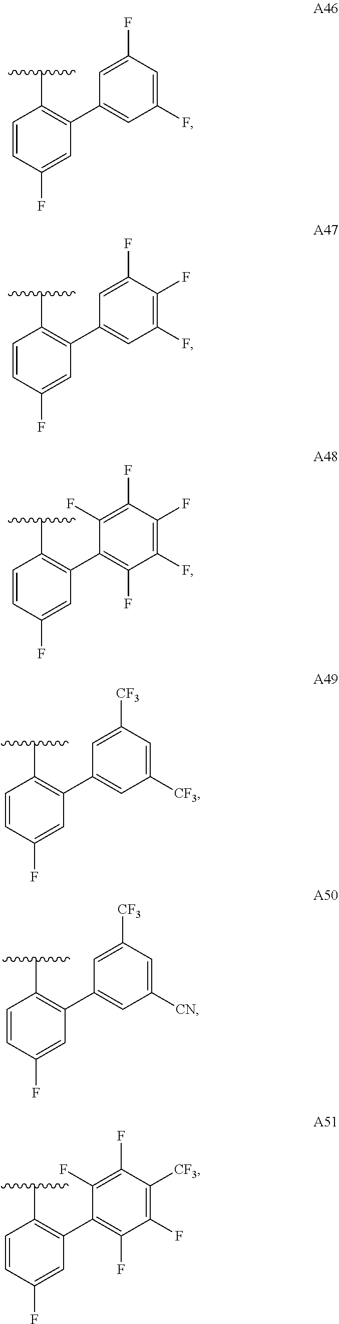 [SMILES: *c1ccc(F)cc1-c1cc(F)cc(F)c1 ; *c1ccc(F)cc1-c1cc(F)c(F)c(F)c1 ; *c1ccc(F)cc1-c1c(F)c(F)c(F)c(F)c1F ; *c1ccc(F)cc1-c1cc(C(F)(F)F)cc(C(F)(F)F)c1 ; *c1ccc(F)cc1-c1cc(C#N)cc(C(F)(F)F)c1 ; *c1ccc(F)cc1-c1c(F)c(F)c(C(F)(F)F)c(F)c1F]

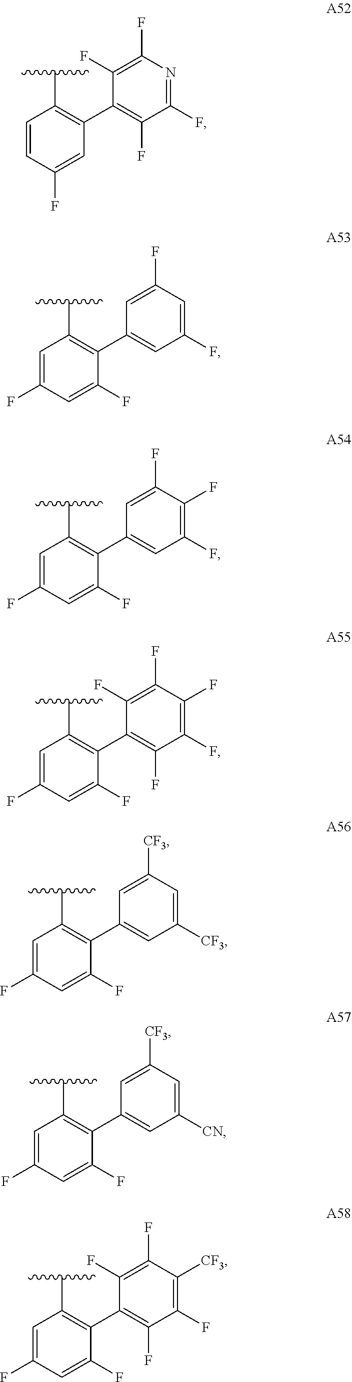

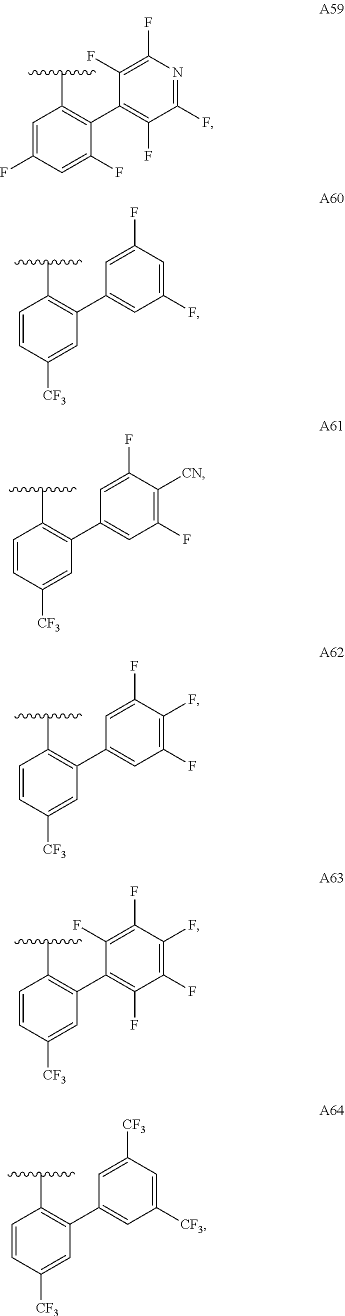

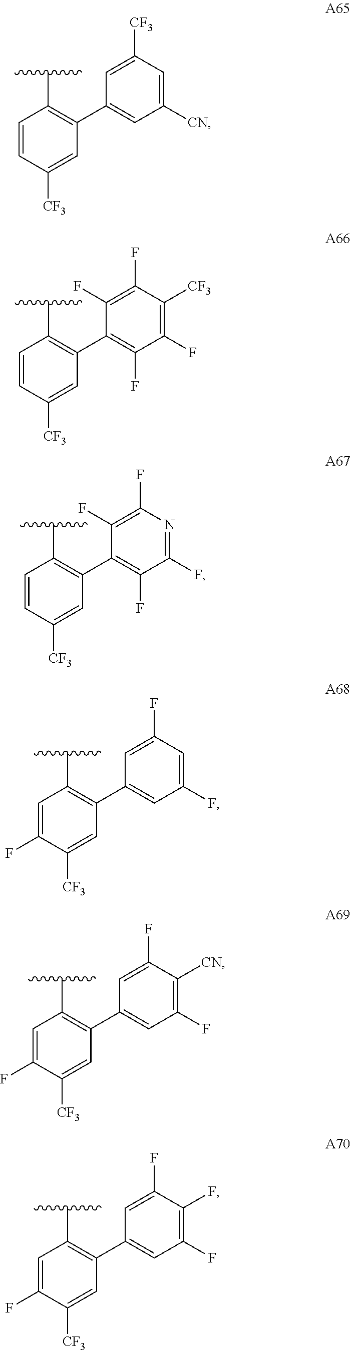 [SMILES: *c1ccc(C(F)(F)F)cc1-c1cc(C#N)cc(C(F)(F)F)c1 ; *c1ccc(C(F)(F)F)cc1-c1c(F)c(F)c(C(F)(F)F)c(F)c1F ; *c1ccc(C(F)(F)F)cc1-c1c(F)c(F)nc(F)c1F ; *c1cc(F)c(C(F)(F)F)cc1-c1cc(F)cc(F)c1 ; *c1cc(F)c(C(F)(F)F)cc1-c1cc(F)c(C#N)c(F)c1 ; *c1cc(F)c(C(F)(F)F)cc1-c1cc(F)c(F)c(F)c1]

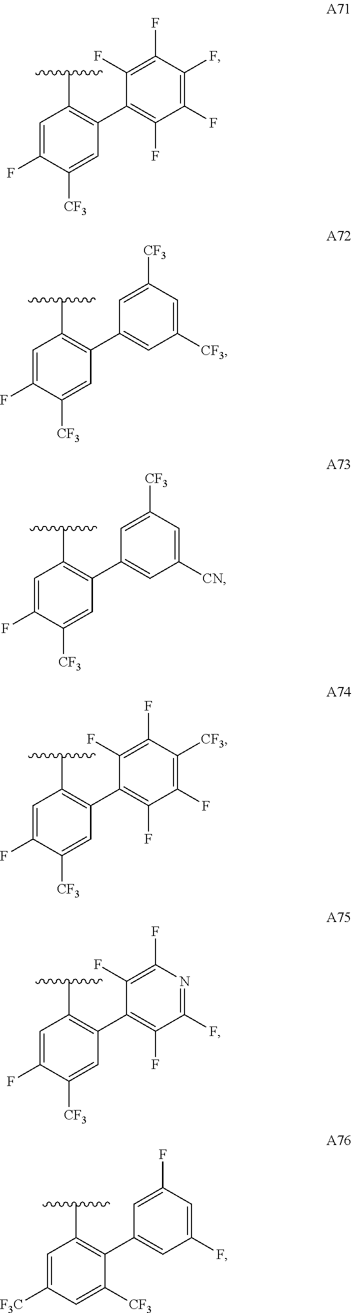 [SMILES: *c1cc(F)c(C(F)(F)F)cc1-c1c(F)c(F)c(F)c(F)c1F ; *c1cc(F)c(C(F)(F)F)cc1-c1cc(C(F)(F)F)cc(C(F)(F)F)c1 ; *c1cc(F)c(C(F)(F)F)cc1-c1cc(C#N)cc(C(F)(F)F)c1 ; *c1cc(F)c(C(F)(F)F)cc1-c1c(F)c(F)c(C(F)(F)F)c(F)c1F ; *c1cc(F)c(C(F)(F)F)cc1-c1c(F)c(F)nc(F)c1F ; *c1cc(C(F)(F)F)cc(C(F)(F)F)c1-c1cc(F)cc(F)c1]

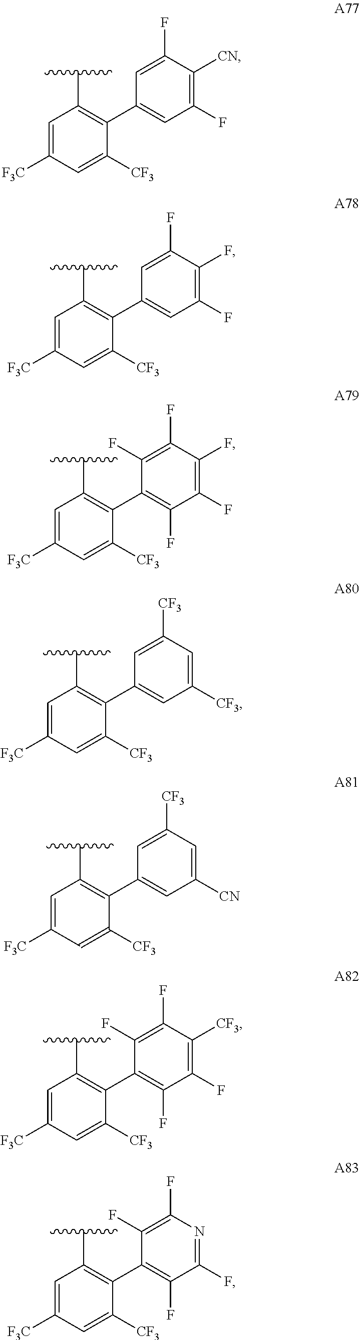

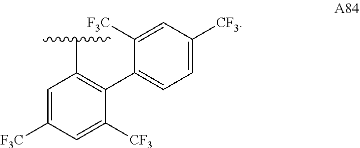 [SMILES: *c1cc(C(F)(F)F)cc(C(F)(F)F)c1-c1ccc(C(F)(F)F)cc1C(F)(F)F]

16. The organic electroluminescent device according to claim 15, wherein the first compound has a structure represented by Formula 1-1: 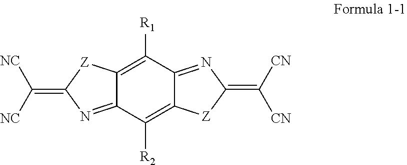
wherein in Formula 1-1, two Z are the same, R₁ is the same as R₂, and Z, R₁ and R₂ are selected from atoms or groups in the following table, respectively:

| No. | Z | R₁ = R₂ | No. | Z | R₁ = R₂ |
|---|---|---|---|---|---|
| PD1 | O | A1 | PD2 | O | A2 |
| PD3 | O | A3 | PD4 | O | A4 |
| PD5 | O | A5 | PD6 | O | A6 |
| PD7 | O | A7 | PD8 | O | A8 |
| PD9 | O | A9 | PD10 | O | A10 |
| PD11 | O | A11 | PD12 | O | A12 |
| PD13 | O | A13 | PD14 | O | A14 |
| PD15 | O | A15 | PD16 | O | A16 |
| PD17 | O | A17 | PD18 | O | A18 |
| PD19 | O | A19 | PD20 | O | A20 |
| PD21 | O | A21 | PD22 | O | A22 |
| PD23 | O | A23 | PD24 | O | A24 |
| PD25 | O | A25 | PD26 | O | A26 |
| PD27 | O | A27 | PD28 | O | A28 |
| PD29 | O | A29 | PD30 | O | A30 |
| PD31 | O | A31 | PD32 | O | A32 |
| PD33 | O | A33 | PD34 | O | A34 |
| PD35 | O | A35 | PD36 | O | A36 |
| PD37 | O | A37 | PD38 | O | A38 |
| PD39 | O | A39 | PD40 | O | A40 |
| PD41 | O | A41 | PD42 | O | A42 |
| PD43 | O | A43 | PD44 | O | A44 |
| PD45 | O | A45 | PD46 | O | A46 |
| PD47 | O | A47 | PD48 | O | A48 |
| PD49 | O | A49 | PD50 | O | A50 |
| PD51 | O | A51 | PD52 | O | A52 |
| PD53 | O | A53 | PD54 | O | A54 |
| PD55 | O | A55 | PD56 | O | A56 |
| PD57 | O | A57 | PD58 | O | A58 |
| PD59 | O | A59 | PD60 | O | A60 |
| PD61 | O | A61 | PD62 | O | A62 |
| PD63 | O | A63 | PD64 | O | A64 |
| PD65 | O | A65 | PD66 | O | A66 |
| PD67 | O | A67 | PD68 | O | A68 |
| PD69 | O | A69 | PD70 | O | A70 |
| PD71 | O | A71 | PD72 | O | A72 |
| PD73 | O | A73 | PD74 | O | A74 |
| PD75 | O | A75 | PD76 | O | A76 |
| PD77 | O | A77 | PD78 | O | A78 |
| PD79 | O | A79 | PD80 | O | A80 |
| PD81 | O | A81 | PD82 | O | A82 |
| PD83 | O | A83 | PD84 | O | A84 |
| PD85 | S | A1 | PD86 | S | A2 |
| PD87 | S | A3 | PD88 | S | A4 |
| PD89 | S | A5 | PD90 | S | A6 |
| PD91 | S | A7 | PD92 | S | A8 |
| PD93 | S | A9 | PD94 | S | A10 |
| PD95 | S | A11 | PD96 | S | A12 |
| PD97 | S | A13 | PD98 | S | A14 |
| PD99 | S | A15 | PD100 | S | A16 |
| PD101 | S | A17 | PD102 | S | A18 |
| PD103 | S | A19 | PD104 | S | A20 |
| PD105 | S | A21 | PD106 | S | A22 |
| PD107 | S | A23 | PD108 | S | A24 |
| PD109 | S | A25 | PD110 | S | A26 |
| PD111 | S | A27 | PD112 | S | A28 |
| PD113 | S | A29 | PD114 | S | A30 |
| PD115 | S | A31 | PD116 | S | A32 |
| PD117 | S | A33 | PD118 | S | A34 |
| PD119 | S | A35 | PD120 | S | A36 |
| PD121 | S | A37 | PD122 | S | A38 |
| PD123 | S | A39 | PD124 | S | A40 |
| PD125 | S | A41 | PD126 | S | A42 |
| PD127 | S | A43 | PD128 | S | A44 |
| PD129 | S | A45 | PD130 | S | A46 |
| PD131 | S | A47 | PD132 | S | A48 |
| PD133 | S | A49 | PD134 | S | A50 |
| PD135 | S | A51 | PD136 | S | A52 |
| PD137 | S | A53 | PD138 | S | A54 |
| PD139 | S | A55 | PD140 | S | A56 |
| PD141 | S | A57 | PD142 | S | A58 |
| PD143 | S | A59 | PD144 | S | A60 |
| PD145 | S | A61 | PD146 | S | A62 |
| PD147 | S | A63 | PD148 | S | A64 |
| PD149 | S | A65 | PD150 | S | A66 |
| PD151 | S | A67 | PD152 | S | A68 |
| PD153 | S | A69 | PD154 | S | A70 |
| PD155 | S | A71 | PD156 | S | A72 |
| PD157 | S | A73 | PD158 | S | A74 |
| PD159 | S | A75 | PD160 | S | A76 |
| PD161 | S | A77 | PD162 | S | A78 |
| PD163 | S | A79 | PD164 | S | A80 |
| PD165 | S | A81 | PD166 | S | A82 |
| PD167 | S | A83 | PD168 | S | A84 |

17. The organic electroluminescent device according to claim 1, wherein the second compound comprises any one or more chemical structural units selected from the group consisting of triarylamine, carbazole, fluorene, spirobifluorene, thiophene, furan, phenyl, oligophenylene ethylene, oligofluorene and combinations thereof;
preferably, the second compound comprises a monotriarylamine structural unit or a bistriarylamine structural unit;
more preferably, the second compound comprises any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit and a bistriarylamine-fluorene structural unit.

18. The organic electroluminescent device according to claim 1, wherein the third compound comprises any one or more chemical structural units selected from the group consisting of: triarylamine, carbazole, fluorene, spirobifluorene, thiophene, furan, phenyl, oligophenylene ethylene, oligofluorene and combinations thereof;
preferably, the third compound is the same as the second compound.

19. The organic electroluminescent device according to claim 1, wherein the first compound is a p-type conductive doping material and the second compound is a hole transporting material.

20. A display apparatus, comprising the organic electroluminescent device according to claim 1.

21. An electronic equipment, comprising the display apparatus according to claim 20.
